(19) United States
(12) Patent Application Publication
(10) Pub. No.: US 2019/0273099 A1
(43) Pub. Date: Sep. 5, 2019

(54) DISPLAY SCREENS AND METHOD OF MANUFACTURING DISPLAY SCREENS, AND DISPLAY DEVICES

(71) Applicant: Yungu (Gu'an) Technology Co., Ltd., Langfang (CN)

(72) Inventor: Lijuan WANG, Langfang (CN)

(21) Appl. No.: 16/414,767

(22) Filed: May 16, 2019

Related U.S. Application Data
(63) Continuation of application No. PCT/CN2018/113506, filed on Nov. 1, 2018.

(30) Foreign Application Priority Data
Apr. 25, 2018 (CN) 201810377760.2

(51) Int. Cl. H01L 27/12; H01L 27/32; H01L 51/52; H01L 51/56

(52) U.S. Cl. CPC H01L 27/1218; H01L 27/3244; H01L 51/5253; H01L 2227/323; H01L 51/56; H01L 27/1262; H01L 51/524

(57) ABSTRACT

Embodiments of the present disclosure relate to display screens and methods of manufacturing display screens, and display devices. A display screen includes a substrate, and at least the first surface of the substrate is provided with a polymer memory layer. When the substrate is deformed or cracked under an external force, the polymer memory layer can automatically restore the initial shape, thereby driving the substrate connected thereto to restore the initial shape, thereby repairing the deformation and fine crack of the substrate.

### CROSS-REFERENCES TO RELATED APPLICATIONS

The present application is a continuation application of International Application No. PCT/CN2018/113506, filed Nov. 1, 2018, which claims the priority to Chinese Application No. 201810377760.2, filed Apr. 25, 2018. The entireties of these applications are incorporated by reference herein for all purposes.

### FIELD

Exemplary embodiments of the present disclosure relate to display technologies, and more particularly, to display screens and methods of manufacturing display screens, and display devices.

### BACKGROUND

Display screens are the parts used in the display for electroluminescence. For example, for a flexible display screen, generally the luminescence principle thereof is that a built-in OLED (Organic Light-Emitting Diode) is driven by a TFT (Thin Film Transistor) array to emit light and display.

Generally, in a conventional flexible display screen, a technical solution of forming a TFT layer on a substrate and forming an OLED layer on the TFT layer is usually adopted to emit light and display normally.

### SUMMARY

In view of the above-mentioned, it is desired to provide display screens and methods of manufacturing display screens, and display devices for addressing the problem that the flexible display screen is prone to cracks after being deformed by an external force, which may lead to poor display of the screen body in the prior art.

According to an aspect of the present disclosure, it is provided a display screen, including: a substrate, wherein at least a first surface of the substrate is provided with a polymer memory layer; a thin-film transistor (TFT) layer overlaying the substrate or on the polymer memory layer; a display layer overlaying the TFT layer; and an encapsulation layer overlaying the TFT layer and the display layer, wherein the encapsulation layer and the TFT layer isolate the display layer from outside.

For the display screen according to this aspect, the substrate is provided with the polymer memory layer, and the TFT layer, the display layer and the encapsulation layer overlie the substrate. The polymer memory layer will restore its initial shape after deformation. When the substrate is deformed or even cracked under an external force, the polymer memory layer will drive the substrate to restore the shape, thereby repairing fine cracks on the substrate. Therefore, when the display screen is deformed and cracked under the external force, the polymer memory layer can automatically restore the initial shape, thereby driving the substrate connected thereto and the TFT layer and the display layer overlaying the substrate to restore the initial shape. Therefore, the display screen can automatically correct its deformation and fine cracks to improve display quality.

In an embodiment, a material of the polymer memory layer includes at least one of norbornene, polyurethane resin, polylactic acid, and polyurethane.

In an embodiment, one of the surfaces of the substrate is provided with the polymer memory layer, the TFT layer overlies a second surface of the substrate opposite to the first surface on which the polymer memory layer is provided, or on the polymer memory layer.

In an embodiment, two surfaces of the substrate are provided with the polymer memory layer, and the TFT layer overlies the polymer memory layer.

In an embodiment, the display layer comprises an OLED layer.

In an embodiment, the encapsulation layer comprises: a first inorganic layer disposed on the TFT layer and the display layer; an organic layer disposed outside the first inorganic layer; a second inorganic layer disposed outside the organic layer.

In an embodiment, the first inorganic layer, the organic layer, and the second inorganic layer are configured in a trapezoidal shape on the TFT layer and the display layer.

According to another aspect of the present disclosure, it is provided a display device, including: the display screen according to the above-mentioned aspect; a cover plate overlaying a side of the display screen on which the encapsulation layer is located for enclosing and protecting the display screen.

The display device according to the aspect adopts the above-mentioned display screen which can correct the deformation and repair the crack by itself, thereby, improving the resistance of the display device to the external force and the display quality thereof.

In an embodiment, at least one surface of the cover plate is provided with the polymer memory layer.

For the display device according to the aspect, at least one surface of the cover plate is also provided with the polymer memory layer, thereby improving the resistance of the cover plate against external force and improving the quality of the display device.

According to still another aspect of the present disclosure, it is provided a method of manufacturing a display screen, including: forming a polymer memory layer on at least a first surface of a substrate; forming a TFT layer on the first surface of the substrate or on the polymer memory layer; forming a display layer on the TFT layer; and forming an encapsulation layer on the TFT layer and the display layer, so that the encapsulation layer and the TFT layer isolate the display layer from outside.

For the method of manufacturing the display screen according to the aspect, the polymer memory layer is formed on at least the first surface of the substrate. When the display screen manufactured by the method is deformed and even cracked under the external force, the polymer memory layer can automatically restore the initial shape, thereby driving the substrate and the TFT layer and the display layer overlaying the substrate to restore the initial shape. Therefore, the method of manufacturing the display screen can repair the fine cracks on the display screen, thereby improving the strength of the screen body and improving the display quality of the display screen.

In an embodiment, the method of forming the polymer memory layer includes one or more selected from processes consisting of spin coating, sputtering, spraying, and screen printing.

In an embodiment, after forming the polymer memory layer on the first surface of the substrate and before forming the TFT layer on the substrate or on the polymer memory layer, the method further includes performing a curing treatment on the polymer memory layer.

In an embodiment, the manner of the curing treatment includes at least one selected from processes consisting of UV curing, cross-linking agent curing, and spontaneous curing.

In an embodiment, forming the encapsulation layer on the TFT layer and the display layer includes: forming a first inorganic layer on the TFT layer and the display layer, so that the first inorganic layer and the TFT layer isolate the display layer from outside; forming an organic layer outside the first inorganic layer, so that the organic layer and the TFT layer isolate the first inorganic layer from outside; forming a second inorganic layer outside the organic layer, so that the second inorganic layer and the TFT layer isolate the organic layer from outside.

In the above-mentioned display screens, display devices, and methods of manufacturing display screens, the substrate provided with the polymer memory layer is used as the base substrate of the display screen, and the polymer memory layer can restore the initial shape after deformation. Therefore, when the display screen and the display device using the substrate generate deformation and fine cracks, the polymer memory layer will drive the substrate, thereby driving the display screen and the display device to restore the initial shape, thereby repairing fine cracks on the display screen and improving the display quality of the display screen.

### BRIEF DESCRIPTION OF THE DRAWINGS

FIG. 1 is a schematic structural diagram illustrating the substrate according to an embodiment of the present disclosure;

FIG. 2 is a schematic structural diagram illustrating the substrate according to another embodiment of the present disclosure;

FIG. 3 is a schematic structural diagram illustrating the substrate according to still another embodiment of the present disclosure;

FIG. 4 is a schematic structural diagram illustrating the display screen according to an embodiment of the present disclosure;

FIG. 5 is a schematic structural diagram illustrating the display screen according to another embodiment of the present disclosure;

FIG. 6 is a schematic structural diagram illustrating the display screen according to still another embodiment of the present disclosure;

FIG. 7 is a schematic structural diagram illustrating the display screen according to still another embodiment of the present disclosure;

FIG. 8 is a process flow diagram illustrating the method of manufacturing a display screen according to an embodiment of the present disclosure;

FIG. 9 is a process flow diagram illustrating forming the encapsulation layer in the method of manufacturing the display screen according to an embodiment of the present disclosure.

Wherein, the meanings represented by the reference numerals are:

10 display screen;

100 substrate;

110 polymer memory layer;

120 TFT layer;

130 display layer;

140 encapsulation layer;

142 first inorganic layer;

144 organic layer;

146 second inorganic layer.

### DETAILED DESCRIPTION OF THE INVENTION

Reference will be made to the drawings to describe embodiments of the present disclosure in detail, so that the above-mentioned objects, features and advantages of the present disclosure can be more apparent and understandable. In the following description, numerous specific details are set forth in order to provide a thorough understanding of the present disclosure. However, the present disclosure can be implemented in many other ways different from those described herein, and those skilled in the art can make similar modifications without departing from the disclosure, and therefore, the present disclosure is not limited by the specific embodiments disclosed below.

In the process of realizing the conventional technology, the applicant found that conventional flexible display screens are prone to cracks after being deformed by external force, which may lead to poor display of the screen body.

For the conventional electronic displays, when cutting or grooving the display screen, or squeezing the display screen with the external force, the display screen may be deformed or even cracked under the external force. When the problem is serious, it may lead to poor display of the screen body, thereby affecting the display quality of the display screen.

In view of the fact that the display screen may be deformed or even cracked under the external force, exemplary embodiments of the present disclosure provides substrates for display screens, display screens and methods of manufacturing display screens, and display devices using display screens.

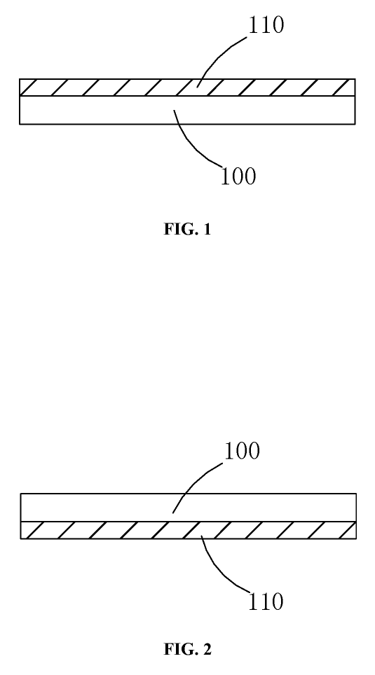

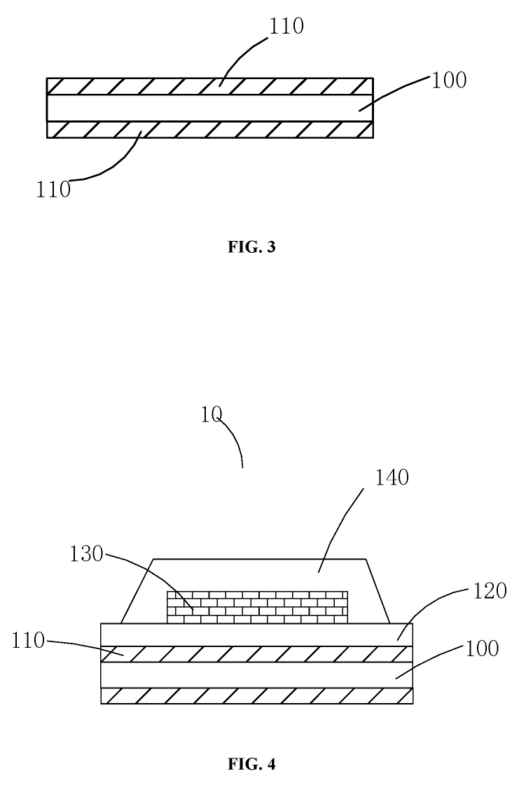

Exemplary embodiments of the present disclosure provide a substrate, as shown in FIG. 1, FIG. 2 and FIG. 3, at least a first surface of the substrate 100 is provided with a polymer memory layer 110.

Specifically, the substrate 100 is used for being deposited a display circuit and a display parts layer by evaporation or other means, and belongs to a substrate layer of the display screen. The substrate 100 may be a flexible glass substrate or a general glass substrate.

The polymer memory layer 110 overlies at least the first surface of the substrate 100. The polymer memory layer 110 should have a function of automatically restoring the initial shape.

In FIG. 1, the polymer memory layer 110 overlies the upper surface of the substrate 100. In FIG. 2, the polymer memory layer 110 overlies the lower surface of the substrate 100. In FIG. 3, the polymer memory layer 110 overlies both the upper and lower surfaces of the substrate 100.

For the above-mentioned substrate 100, at least the first surface is provided with the polymer memory layer 110. The polymer memory layer 110 has an initial shape and has the function of automatically restoring the initial shape after the initial shape being changed under certain conditions. When the substrate 100 is deformed or cracked under the external force, the polymer memory layer 110 can automatically restore the initial shape, thereby driving the substrate 100 connected thereto to restore the initial shape, thereby repairing the deformation and fine cracks of the substrate 100.

It should be noted that the above-mentioned polymer memory layer that can automatically restore the initial shape does not only refer to a material capable of restoring the initial shape under natural conditions, but also includes a material capable of restoring the initial shape under certain external conditions. For example, for a polymer memory layer, when the temperature of the polymer memory layer rises to 30° C., the polymer memory layer will have the function of restoring the initial shape. At this time, the temperature does not affect the normal use of the glass substrate, and at this temperature, the function of repairing the deformation and fine cracks of the substrate can be realized. Therefore, it is not limited whether the material of the polymer memory layer of the present disclosure requires external conditions to restore the initial shape.

As shown in FIG. 4, Exemplary embodiments of the present disclosure further provide a display screen 10 including a substrate 100, a TFT layer 120, a display layer 130, and an encapsulation layer 140.

Specifically, the TFT layer 120 is deposited on the substrate 100 that is used as the substrate layer of the display screen 10 by vapor deposition, sputtering, or other means. At least the first surface of the substrate 100 is provided with the polymer memory layer 110. The polymer memory layer 110 has the function of automatically restoring the initial shape.

The TFT layer 120 overlies the substrate 100 or the polymer memory layer 110 for driving the display layer 130 to emit light. A material of the TFT layer 120 may be one or more selected from the group consisting of amorphous silicon, single crystal silicon, and tin indium oxide. When the upper and lower surfaces of the substrate 100 are both provided with the polymer memory layer 110, the TFT layer 120 overlies the polymer memory layer 110. When the lower surface of the substrate 100 is provided with the polymer memory layer 110, the TFT layer 120 overlies the upper surface of the substrate 100. When the upper surface of the substrate 100 is provided with the polymer memory layer 110, the TFT layer 120 overlies the polymer memory layer 110.

The display layer 130 overlies the TFT layer 120 and driven by the TFT layer 120. When the TFT layer 120 drives the display layer 130, the display layer 130 will emit light.

The encapsulation layer 140 overlies the TFT layer 120 and the display layer 130. The encapsulation layer 140 and the TFT layer 120 isolate the display layer 130 from outside to achieve the effect of encapsulating the display layer 130.

More specifically, the display screen 10 in the present embodiment includes the substrate 100, and at least the first surface of the substrate 100 is provided with the polymer memory layer 110. The TFT layer 120 overlies the substrate 100 or on the polymer memory layer 110 for driving the display layer 130 which overlies the TFT layer 120. The encapsulation layer 140 overlies the TFT layer 120 and the display layer 130. The encapsulation layer 140 isolates the display layer 130 from outside to prevent outside air or water molecules from entering the display layer 130 and damaging the normal operation of the display layer 130.

The above-mentioned display screen 10 employs the above-mentioned substrate 100 provided with the polymer memory layer 110, and the TFT layer 120, the display layer 130, and the encapsulation layer 140 overlie the substrate 100. When the display screen 10 is deformed and cracked under the external force, the polymer memory layer 110 can automatically restore the original shape, thereby driving the substrate 100 connected thereto and the TFT layer 120 and the display layer 130 overlaying the substrate 100 to restore the original shape. Therefore, the display screen 10 can automatically correct its deformation and fine cracks to improve display quality.

In an embodiment, for the substrate in the display screen of the present disclosure, the material of the polymer memory layer may be one or more selected from the group consisting of norbornene, polyurethane resin, polylactic acid, and polyurethane.

It should be understood that all the materials of the polymer memory layer cannot be exhaustive in the present embodiment. Therefore, if a certain material can realize the function of automatically restoring the initial shape under natural conditions, or under certain conditions, the material should be understood to be within the scope of protection of the present embodiment.

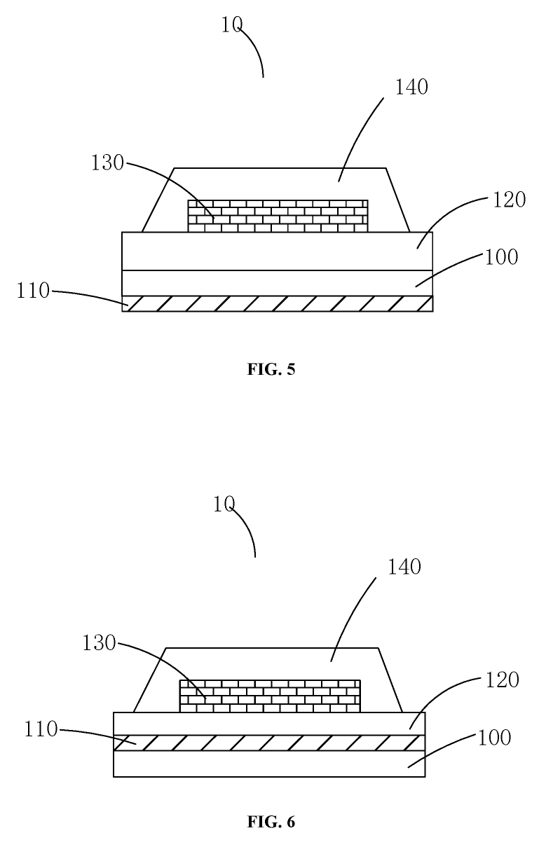

In an embodiment, as shown in FIG. 4, when both the upper and lower surfaces of the substrate 100 are provided with the polymer memory layer 110, the TFT layer 120 overlies the polymer memory layer 110. As shown in FIG. 5, when the lower surface of the substrate 100 is provided with the polymer memory layer 110, the TFT layer 120 overlies the upper surface of the substrate 100. As shown in FIG. 6, when the upper surface of the substrate 100 is provided with the polymer memory layer 110, the TFT layer 120 overlies the polymer memory layer 110.

In an embodiment, for the above-mentioned display screen, the display layer may specifically be an OLED layer. The OLED layer may include an anode metal layer, an organic light emitting layer, and a cathode metal layer. In the present embodiment, the anode metal layer overlies the TFT layer, the organic light emitting layer overlies the anode metal layer, and the cathode metal layer overlies the organic light emitting layer. When the TFT layer drives the OLED layer, electrons will move between the anode metal layer and the cathode metal layer to generate electric current, thereby causing the organic light emitting layer to emit light. The encapsulation layer overlies the TFT layer and the OLED layer to isolate the OLED layer from outside.

For the above-mentioned display screen, the display layer uses the OLED as a light-emitting display parts. An encapsulation layer is further provided outside the OLED layer, and the encapsulation layer is provided to prevent the organic light emitting layer and the cathode metal layer constituting the OLED layer from being oxidized by water-oxygen molecules in the air and affecting the normal operation of the OLED layer and degrading the display quality of the display screen.

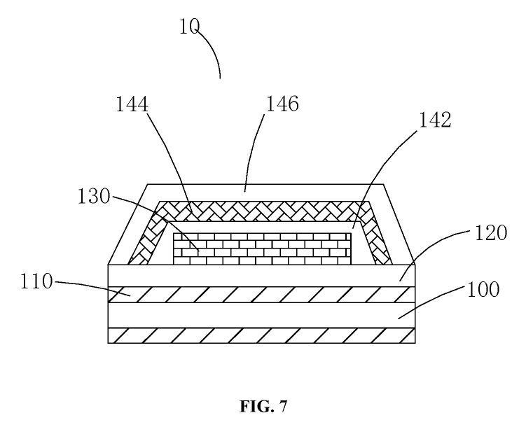

In an embodiment, as shown in FIG. 7, the above-mentioned display screen includes the substrate 100, the polymer memory layer 110 overlaying the upper and lower surfaces of the substrate 100, the TFT layer 120 overlaying the polymer memory layer 110 of the upper surface of the substrate 100, the display layer 130 overlaying the TFT layer 120, and the encapsulation layer overlaying the TFT layer 120 and the display layer 130. The encapsulation layer is used to isolate the display layer 130 from outside.

The encapsulation layer 140 includes a first inorganic layer 142, an organic layer 144, and a second inorganic layer 146.

Specifically, the first inorganic layer 142 overlies the TFT layer 120 and the display layer 130, so that the display layer 130 is isolated from outside by the first inorganic layer 142 and the TFT layer 120.

The organic layer 144 overlies the first inorganic layer 142 and the TFT layer 120, so that the first inorganic layer 142 is isolated from outside by the organic layer 144 and the TFT layer 120.

The second inorganic layer 146 overlies the organic layer 144 and the TFT layer 120, so that the organic layer 144 is isolated from outside by the second inorganic layer 146 and the TFT layer 120.

The first inorganic layer 142, the organic layer 144, and the second inorganic layer 146 may be configured in a trapezoidal shape on the TFT layer 120 and the display layer 130, so that the display layer 130 is protected by the encapsulation layer 140 as much as possible while improving the stability of the encapsulation layer 140.

The display screen 10 adopts an encapsulation technology in which organic and inorganic layers are stacked and encapsulated to ensure that the OLED layer does not come into contact with water-oxygen molecules in outside air as much as possible, thereby prolonging the operating life of the display screen 10 and improving the display quality.

Exemplary embodiments of the present disclosure further provide a display device including a display screen and a cover plate.

The display screen is the display screen described in any one of the above-mentioned embodiments, that is, the polymer memory layer overlies at least the first surface of the substrate used in the display screen.

The cover plate overlies a side of the display screen on which the encapsulation layer is located to enclose and protect the display screen.

The display device adopts the display screen which can correct the deformation and repair the crack by itself, thereby, improving the resistance of the display device against the external force and improving the display quality thereof.

In an embodiment, in the above-mentioned display device, at least one surface of the cover plate is provided with the polymer memory layer.

Specifically, the above-mentioned display device includes the display screen and the cover plate. The cover plate is used to enclose and protect the display screen. At least the first surface of the substrate of the display screen is provided with the polymer memory layer, and at least one surface of the cover plate is also provided with the polymer memory layer.

For the above-mentioned display device, at least one surface of the cover plate thereof is also provided with the polymer memory layer, thereby improving the resistance of the cover plate against external force and improving the quality of the display device.

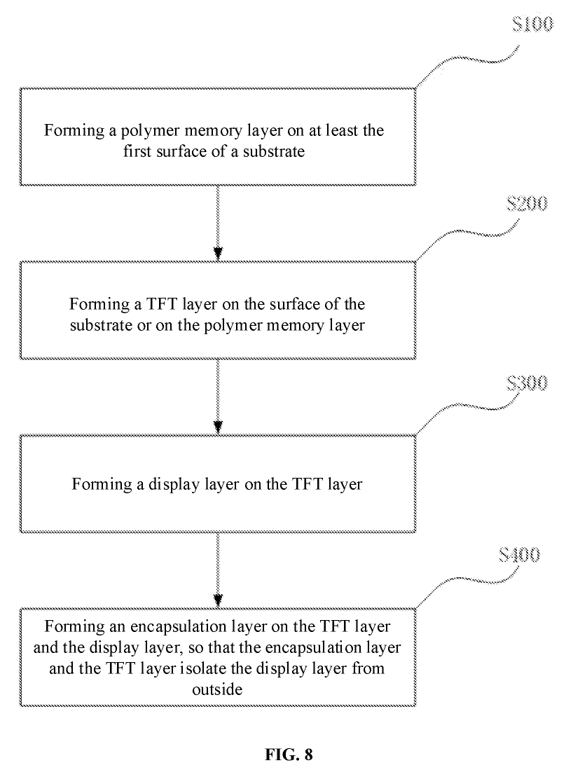

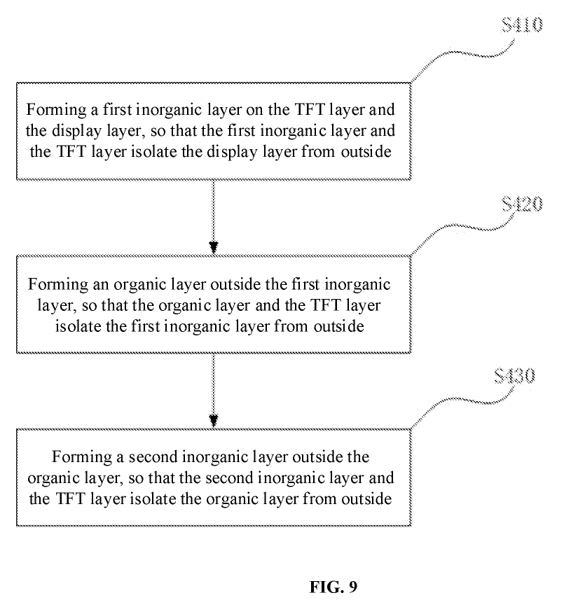

Exemplary embodiments of the present disclosure also provide a method of manufacturing a display screen, as shown in FIG. 8, the method of manufacturing the display screen includes the following steps:

S100, forming a polymer memory layer on at least the first surface of a substrate.

The polymer memory layer is formed on the first surface of the substrate, or the polymer memory layer is formed on both the upper and lower surfaces of the substrate. The polymer memory layer should have the function of automatically restoring the initial shape under natural conditions or under other specific conditions. The method of forming the polymer memory layer includes one or more selected from the processes consisting of spin coating, sputtering, spraying, and screen printing. The material of the polymer memory layer may be one or more selected from the group consisting of norbornene, polyurethane resin, polylactic acid, and polyurethane.

S200, forming a TFT layer on the first surface of the substrate or on the polymer memory layer.

If two surfaces of the substrate are provided with the polymer memory layer, the TFT layer will be formed on the polymer memory layer on one of the surfaces of the substrate. If the only the first surface of the substrate is provided with the polymer memory layer, the TFT layer may overlie a second surface of the substrate or on the polymer memory layer. The method of forming the TFT layer includes one or more of vapor deposition, sputtering, and the like.

S300, forming a display layer on the TFT layer.

The display layer is formed on the TFT layer, the TFT layer is used to drive the display layer to emit light, and the display layer is used to emit light. The display layer includes the OLED layer or other illuminable parts layer. The method of forming the display layer includes one or more of vacuum evaporation, inkjet printing, and the like.

S400, forming an encapsulation layer on the TFT layer and the display layer, so that the encapsulation layer and the TFT layer isolate the display layer from outside.

The encapsulation layer is formed on the TFT layer and the display layer, so that the encapsulation layer and the TFT layer isolate the display layer from outside. The encapsulation layer is used to insulate outside air, water molecules, etc. from contacting the display layer and destroying the display layer. The method of forming the encapsulation layer includes one or more of vapor deposition, inkjet printing, and the like.

In the above-mentioned method of manufacturing the display screen, the polymer memory layer is formed on at least the first surface of the substrate, and then the substrate is used to prepare a display screen. When the display screen manufactured by the method is deformed and even cracked under the external force, the polymer memory layer can automatically restore the initial shape, thereby driving the substrate and the TFT layer and the display layer overlaying the substrate to restore the initial shape. Therefore, the method of manufacturing the display screen can repair the fine cracks on the display screen, thereby improving the strength of the screen body and improving the display quality of the display screen.

In an embodiment, in the above-mentioned method of manufacturing the display screen, after forming the polymer memory layer on the first surface of the substrate (step S100) and before forming a TFT layer on the first surface of the substrate or on the polymer memory layer (step S200), it further includes the following steps:

S101, performing a curing treatment on the polymer memory layer.

That is, after forming the polymer memory layer on the first surface of the substrate, the curing treatment should be performed on the polymer memory layer. Different polymer memory layers correspond to different curing treatment methods. Generally, the curing treatment methods include one or more selected from processes consisting of UV curing, cross-linking agent curing, and spontaneous curing.

It should be understood that, in the step of S101, the purpose of performing the curing treatment on the polymer memory layer is to carry out the next process, that is, in the step of S200, the TFT layer is formed on the surface of the substrate or on the polymer memory layer. Therefore, when the polymer memory layer overlies the first surface of the substrate and the TFT layer overlies the second surface of the substrate, the step S101 is not necessary in the method of manufacturing the display screen of the present disclosure. The step S101 does not have to be before the step S200.

In an embodiment, as shown in FIG. 7, in the method of manufacturing the display screen of the present disclosure, the method of forming the encapsulation layer may specifically be:

S410, forming a first inorganic layer on the TFT layer and the display layer, so that the first inorganic layer and the TFT layer isolate the display layer from outside.

After forming the display layer on the TFT layer, the first inorganic layer is formed on the TFT layer and the display layer. The first inorganic layer covers the display layer from above. Therefore, the first inorganic layer and the TFT layer isolate the display layer from outside.

S420, forming an organic layer outside the first inorganic layer, so that the organic layer and the TFT layer isolate the first inorganic layer from outside.

After forming the first inorganic layer, the organic layer is formed outside the first inorganic layer. The organic layer covers the first inorganic layer from above. Therefore, the organic layer and the TFT layer isolate the first inorganic layer from outside.

S430, forming a second inorganic layer outside the organic layer, so that the second inorganic layer and the TFT layer isolate the organic layer from outside.

After forming the organic layer, the second inorganic layer is formed outside the organic layer. The second inorganic layer covers the organic layer from above. Therefore, the second inorganic layer and the TFT layer isolate the organic layer from outside.

Each of the technical features of the above-described embodiments may be combined arbitrarily. To simplify the description, all the possible combinations of each of the technical features in the above embodiments are not described. However, all of the combinations of these technical features should be considered as within the scope of the present specification, as long as such combinations do not contradict with each other.

The above-described embodiments merely represent several embodiments of the present disclosure, and the description thereof is more specific and detailed, but it should not be construed as limiting the scope of the present disclosure. It should be noted that, for a person skilled in the art, several variations and improvements may be made without departing from the concept of the present disclosure, and these are all within the protection scope of the present disclosure. Therefore, the protection scope of the present disclosure shall be subject to the appended claims.

1. A display screen comprising:
a substrate, at least a first surface of the substrate being provided with a polymer memory layer;
a thin-film transistor (TFT) layer overlaying the substrate or overlaying the polymer memory layer;
a display layer overlaying the TFT layer; and
an encapsulation layer overlaying the TFT layer and the display layer, the encapsulation layer and the TFT layer isolating the display layer from outside.

2. The display screen of claim 1, wherein a material of the polymer memory layer comprises at least one of norbornene, polyurethane resin, polylactic acid, and polyurethane.

3. The display screen of claim 1, wherein the first surface of the substrate is provided with the polymer memory layer, the TFT layer overlies a second surface of the substrate opposite to the first surface on which the polymer memory layer is provided, or on the polymer memory layer.

4. The display screen of claim 1, wherein two surfaces of the substrate are provided with the polymer memory layer, and the TFT layer overlies the polymer memory layer.

5. The display screen of claim 1, wherein the display layer comprises an OLED layer.

6. The display screen of claim 1, wherein the encapsulation layer comprises:
a first inorganic layer disposed on the TFT layer and the display layer;
an organic layer disposed outside the first inorganic layer; and
a second inorganic layer disposed outside the organic layer.

7. The display screen of claim 6, wherein the first inorganic layer, the organic layer, and the second inorganic layer are configured in a trapezoidal shape on the TFT layer and the display layer.

8. A display device comprising:
the display screen of claim 1;
a cover plate overlaying a side of the display screen on which the encapsulation layer is located for enclosing and protecting the display screen.

9. The display device of claim 8, wherein at least one surface of the cover plate is provided with the polymer memory layer.

10. A method of manufacturing a display screen, comprising:
forming a polymer memory layer on at least a first surface of a substrate;
forming a TFT layer on the first surface of the substrate or on the polymer memory layer;
forming a display layer on the TFT layer; and
forming an encapsulation layer on the TFT layer and the display layer, so that the encapsulation layer and the TFT layer isolate the display layer from outside.

11. The method of claim 10, wherein the method of forming the polymer memory layer comprises at least one selected from processes consisting of spin coating, sputtering, spraying, and screen printing.

12. The method of claim 10, wherein after forming the polymer memory layer on the first surface of the substrate, further comprising:
performing a curing treatment on the polymer memory layer.

13. The method of claim 12, wherein the manner of the curing treatment comprises at least one selected from processes consisting of UV curing, cross-linking agent curing, and spontaneous curing.

14. The method of claim 10, wherein forming the encapsulation layer on the TFT layer and the display layer comprises:
forming a first inorganic layer on the TFT layer and the display layer, so that the first inorganic layer and the TFT layer isolate the display layer from outside;
forming an organic layer outside the first inorganic layer, so that the organic layer and the TFT layer isolate the first inorganic layer from outside;
forming a second inorganic layer outside the organic layer, so that the second inorganic layer and the TFT layer isolate the organic layer from outside.
